(19) United States
(12) Patent Application Publication
(10) Pub. No.: US 2006/0244478 A1
(43) Pub. Date: Nov. 2, 2006

(54) Systems and methods for reducing signal ringing

(76) Inventors: Kent Smith, Holladay, UT (US); Tracy Johancsik, Murray, UT (US)

Correspondence Address: STEVEN L. NICHOLS;RADER, FISHMAN & GRAVER PLLC, 10653 S. RIVER FRONT PARKWAY, SUITE 150, SOUTH JORDAN, UT, 84095, US

(21) Appl. No.: 11/415,608

(22) Filed: May 1, 2006

Related U.S. Application Data
(60) Provisional application No. 60/676,423, filed on Apr. 29, 2005.

(51) Int. Cl. H03K 19/003

(52) U.S. Cl. 326/27

(57) ABSTRACT

Systems for reducing ringing of a signal generated by a digital signal source circuit include a number of driver circuits configured to incrementally increase an output impedance of the source circuit. The increase in output impedance is configured to reduce the ringing of the signal. Methods of reducing ringing of a signal generated by a digital signal source circuit include incrementally increasing an output impedance of the source circuit. The increase in output impedance is configured to reduce the ringing of the signal.

### RELATED APPLICATIONS

The present application claims the benefit under 35 U.S.C. § 119(e) of Provisional Application Ser. No. 60/676,423, filed Apr. 29, 2005, which is incorporated herein by reference in its entirety.

### BACKGROUND

In many digital circuit configurations, it is desirable to be able to transmit data from one component to another at a high rate. Such transmission often occurs via one or more transmission lines. These transmission lines may include, but are not limited to, chip bond wires, circuit board wiring, and traces. However, transmission lines inherently have a parasitic inductance, resistance, and capacitance; all of which may limit the speed at which transmissions occur.

In particular, the parasitic inductance and capacitance of a transmission line and of other components within the digital circuit can cause the signals on the transmission line to “ring” when they switch from one voltage state (e.g., low) to another (e.g., high). In other words, the voltage or current of the signals oscillates undesirably. Such ringing must be allowed to settle before the data on a transmission line can be received, thereby adding to the total transmission time.

A number of additional problems are associated with signal ringing. For example, signal ringing causes extra current to flow within a digital circuit, thereby wasting energy and causing excessive component heating. Moreover, signal ringing may also cause electromagnetic interference (EMI), which may be detrimental to nearby electronic components. Signal ringing may also cause unwanted triggering of bistable elements within a digital circuit.

A number techniques are currently used to reduce signal ringing. However, many of these techniques have undesirable side effects or are limited in their application. For example, one common technique to reduce signal ringing is to insert a resistor (e.g., a 100 ohm resistor) in series with the transmission line in order to attenuate signal ringing. However, this technique is less effective with high frequency signals, reduces slew rates, and requires additional components.

Impedance matching is also used to reduce signal ringing. In impedance matching, the impedance of a signal output driver is designed to match the characteristic impedance of the transmission line. However, impedance matching may be rendered ineffective by bond wire inductance, bends in circuit board wiring, or changes in the impedance of the transmission line.

Another common technique used to reduce ringing of a signal is to reduce the signal's edge slew rate. A reduction in edge slew rate may be achieved by decreasing the impedance of the signal output driver over time. However, this technique depends on the frequency of the signal and can result in undesirable delays.

### SUMMARY

Systems for reducing ringing of a signal generated by a digital signal source circuit include a number of driver circuits configured to incrementally increase an output impedance of the source circuit. The increase in output impedance is configured to reduce the ringing of the signal.

Methods of reducing ringing of a signal generated by a digital signal source circuit include incrementally increasing an output impedance of the source circuit. The increase in output impedance is configured to reduce the ringing of the signal.

### BRIEF DESCRIPTION OF THE DRAWINGS

The accompanying drawings illustrate various embodiments of the principles described herein and are a part of the specification. The illustrated embodiments are merely examples and do not limit the scope of the disclosure.

FIG. 1 illustrates an exemplary configuration wherein a digital signal source is configured to generate and transmit one or more digital signals to a receiving circuit via a transmission line according to principles described herein.

FIG. 2 is a graph representative of an under-damped system according to principles described herein.

FIG. 3 is a graph representative of an over-damped system according to principles described herein

FIG. 4 is representative of a critically damped system according to principles described herein.

FIG. 5 illustrates an exemplary system for reducing signal ringing wherein a resistor is placed in series with a transmission line.

FIG. 6 is a diagram showing circuitry configured to match the output impedance of the digital signal source to the impedance of the transmission line according to principles described herein.

FIG. 7 is a diagram illustrating exemplary circuitry configured to reduce ringing by incrementally increasing the output impedance of the digital signal source according to principles described herein.

FIG. 8 is a timing diagram that illustrates an exemplary method of operation of the circuit of FIG. 7 according to principles described herein.

Throughout the drawings, identical reference numbers designate similar, but not necessarily identical, elements.

### DETAILED DESCRIPTION

Systems for reducing ringing of a signal generated by a digital signal source circuit are described herein. The digital signal source circuit includes a number of driver circuits configured to incrementally increase the output impedance of the source circuit. In this manner, signal ringing may be reduced while not significantly affecting rise and fall times of the signal.

In the following description, for purposes of explanation, numerous specific details are set forth in order to provide a thorough understanding of the present systems and methods. It will be apparent, however, to one skilled in the art that the present systems and methods may be practiced without these specific details. Reference in the specification to “one embodiment” or “an embodiment” means that a particular feature, structure, or characteristic described in connection with the embodiment is included in at least one embodiment. The appearance of the phrase “in one embodiment” in various places in the specification are not necessarily all referring to the same embodiment.

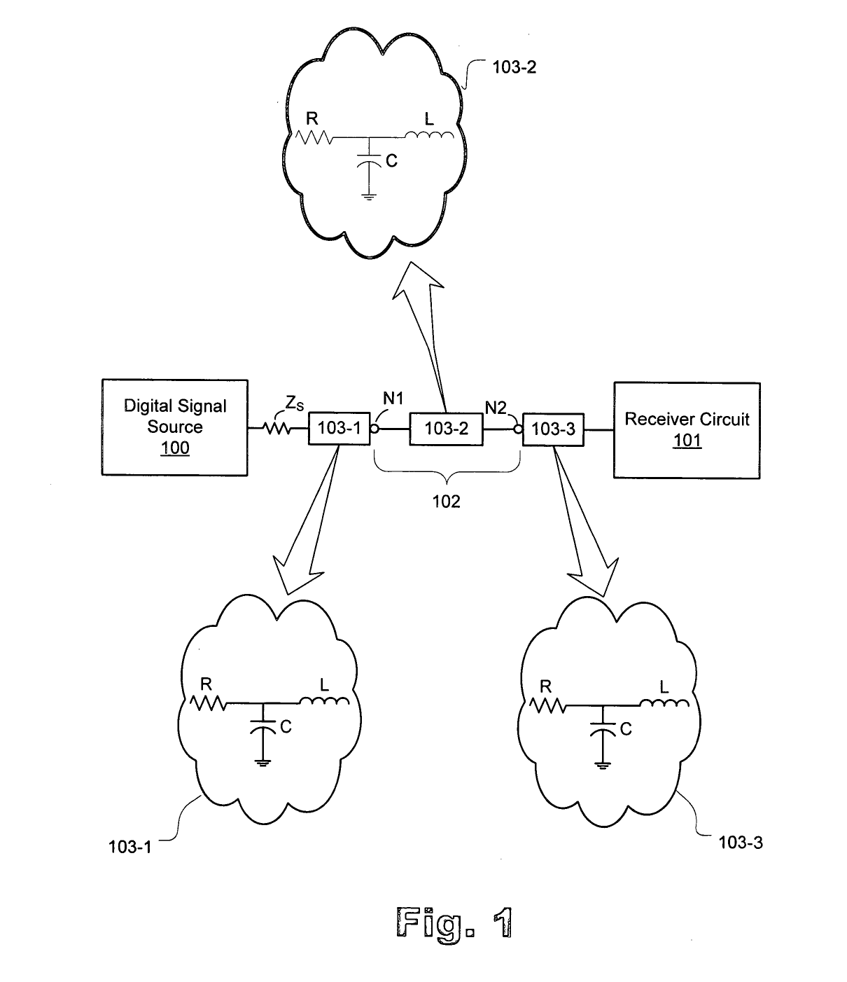

Referring to FIG. 1, a circuit is shown which incorporates a digital signal source (100) that is configured to generate and transmit one or more digital signals to a receiving circuit (101) via a transmission line (102). The digital signal source (100) has output impedance Z_{S} and may include any type of integrated circuit, such as a CMOS integrated circuit, programmable logic device, microprocessor, digital signal processor (DSP), memory circuit, application specific integrated circuit (ASIC), and/or field programmable gate array (FPGA). Additionally or alternatively, the digital signal source (100) may include any other combination of hardware, software, and firmware configured to generate a digital signal. Likewise, the receiving circuit (101) may include any of the aforementioned integrated circuits and/or any other combination of hardware, software, and firmware configured to receive a digital signal.

As shown in FIG. 1, the transmission line (102) begins at node N1 and terminates at node N2. The transmission line (102) may include, but is not limited to, a cable, wire, chip bond wire, circuit board wiring, circuit board trace, and/or any other type of conductive transmission path.

As mentioned, a signal transmitted along the transmission line (102) may ring when it switches from one voltage state (e.g., low) to another (e.g., high). Signal ringing is caused by parasitic components inherently incorporated into each of the components which make up and are connected to the transmission line (102). This is shown in FIG. 1 wherein reference numeral 103-1 identifies the parasitic components for the digital signal source (100), reference numeral 103-2 identifies the parasitic components for the transmission line (102), and reference numeral 103-3 identifies the parasitic components for the receiver circuit (100). As shown in FIG. 1, the digital signal source (100), transmission line (102) and receiver circuit (101) each include a parasitic inductance (L), parasitic capacitance (C), and parasitic resistance (R).

Due to the parasitic components (103), the transmission line voltage does not change as a step function when it switches from a first voltage state (e.g., low) to a second voltage state (e.g., high). Instead, the transmission line voltage rings during the transition between voltage states. The present systems and methods, as will be described in more detail below, may serve to reduce or eliminate such signal ringing.

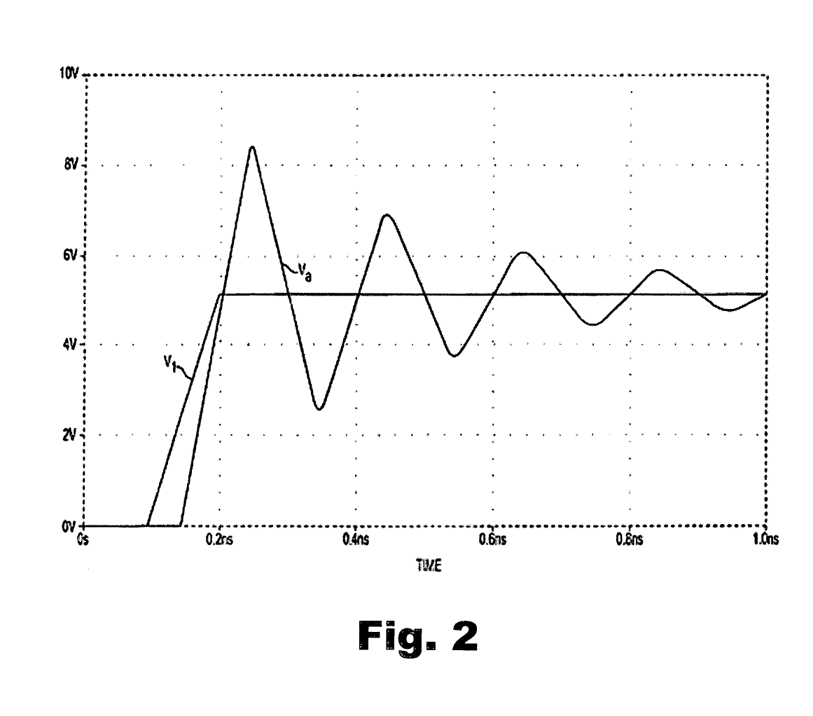

To facilitate an understanding of the systems and methods described herein, a brief explanation of over-damped, critically damped, and under-damped systems will now be given in connection with FIGS. 2-4. Specifically FIGS. 2-4 display a signal Va, at node N2, as compared to an input signal V1 to the transmission line (102) of FIG. 1.

FIG. 2 represents the value of the signal Va, at node N2, propagated through the circuit depicted in FIG. 1 and is representative of an under-damped system. More specifically, FIG. 2 represents a case where there are signal reflections at the source end, node N1, and where the output impedance Z_{S} of the source (100; FIG. 1) is small. Hence, there is relatively little attenuation of the reflected signal before it reaches node N2. As a result, the signal Va does not stay steady or match the input signal V1.

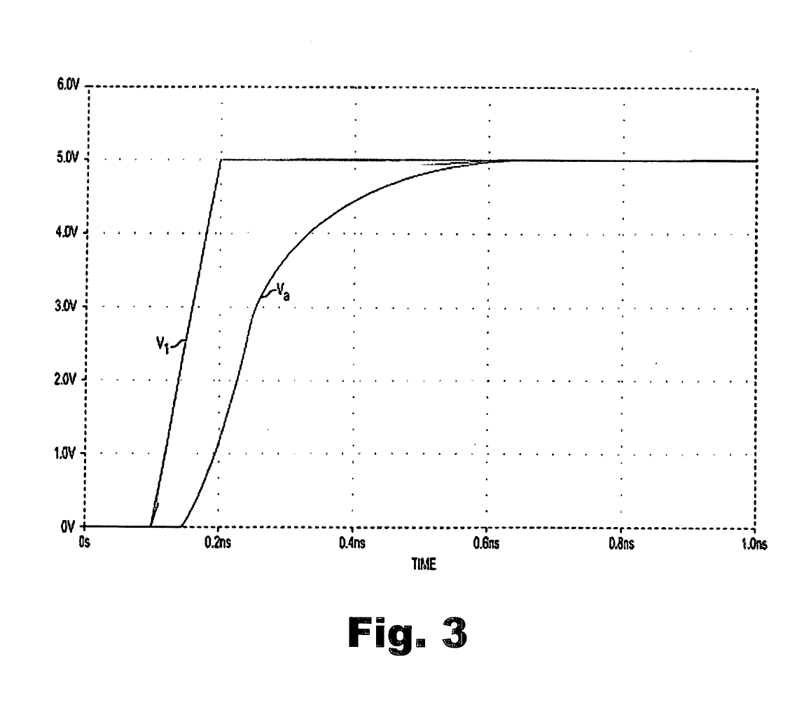

FIG. 3 is representative of an over-damped system. FIG. 3 represents a case where signal reflections are minimized at the source end, node N1, by having a source with a large output impedance Z_{S}. As shown in FIG. 3, the signal Va is heavily delayed and slow to rise as compared to the input signal V1. Such a slow rise time is undesirable in many digital circuit applications.

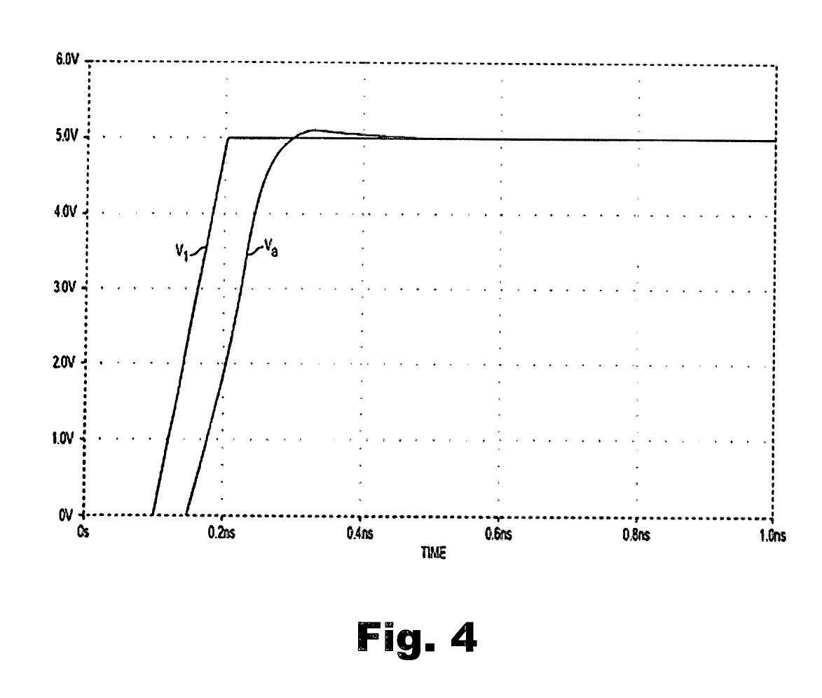

FIG. 4 is representative of a critically damped system. FIG. 4 represents a case where there is sufficient attenuation of reflected signals before they are received at node N2. In other words, the output impedance Z_{S} of the source (100; FIG. 1) and/or the impedance of the transmission line (102; FIG. 1) are such that the reflected signals are prevented from being sent all the way back to node N2. For example, as shown in FIG. 4, the signal Va may be slightly delayed by the time it takes to travel down the transmission line (102; FIG. 1) (e.g., about 50 ps). However, the signal Va substantially follows the input signal V1. As can be seen in a comparison of FIGS. 2-4, the critically damped system of FIG. 4 is advantageous in many digital circuit designs because it minimizes ringing without causing significant delay of Va.

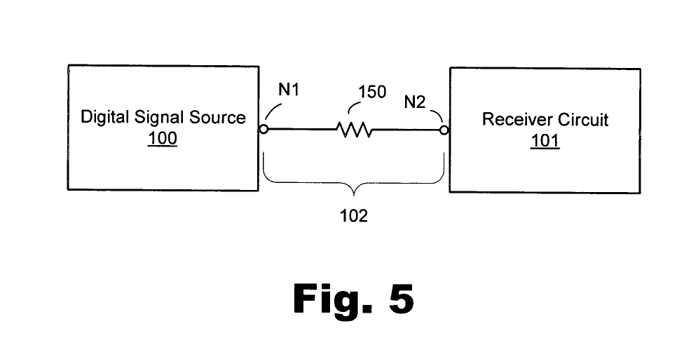

As mentioned, a number of techniques are currently used to reduce signal ringing. However, many of these techniques have undesirable side effects or are limited in their application. For example, FIG. 5 illustrates an exemplary system for reducing signal ringing wherein a resistor (150) is placed in series with the transmission line (102). The resistor (150) is configured to attenuate the signal in order to minimize signal ringing. However, the system of FIG. 5 is less effective in systems with high frequency signals and reduces the slew rates of the signal.

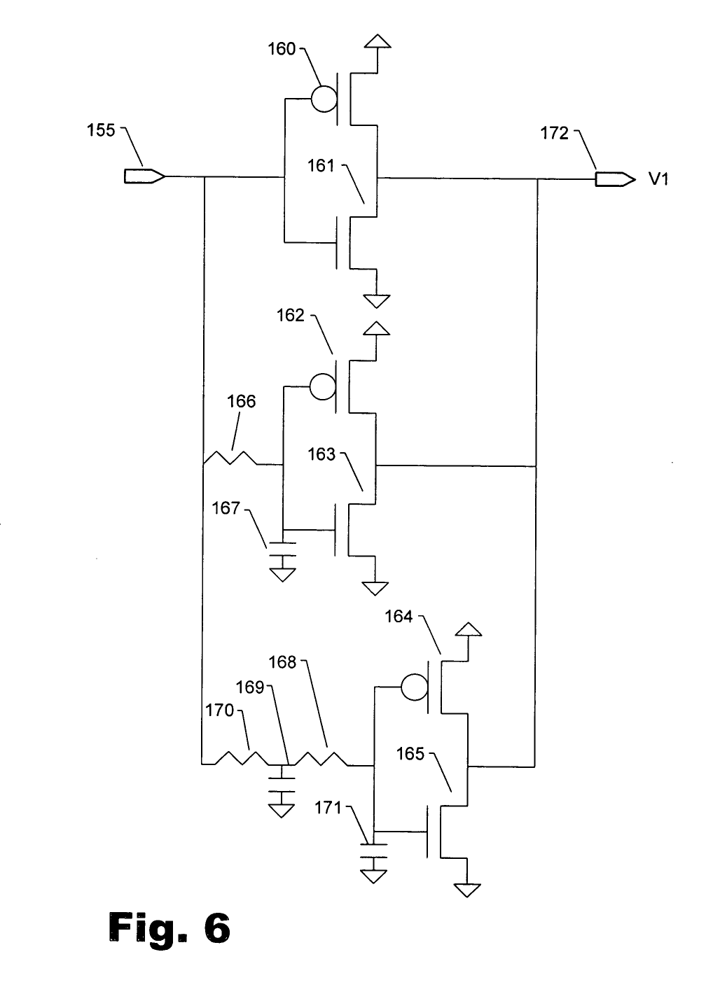

Signal ringing may also be reduced by matching the output impedance Z_{S} of the source (100) with the impedance of the transmission line (102). FIG. 6 is a diagram showing circuitry that may be included within the digital signal source (100; FIG. 1) that is configured to match the impedance of the transmission line (102; FIG. 1). As shown in FIG. 6, the circuitry is connected to an input signal (155) generated by the source (100; FIG. 1) and is configured to generate the output signal V1 (172). The output signal V1 (172) may then be transmitted to the receiving circuit (101; FIG. 1) via the transmission line (102; FIG. 1). The values of the transistors shown in FIG. 6 may be chosen such that the output impedance Z_{S} of the source (100; FIG. 1) is matched with the transmission line (102; FIG. 1).

As shown in FIG. 6, the circuitry may include a first driver circuit having a PMOS transistor (160) and an NMOS transistor (161). The circuitry may also include a second driver circuit having a PMOS transistor (162) and an NMOS transistor (163). As shown in FIG. 6, the second driver circuit is in parallel with the first driver circuit and includes resistor (166) and capacitor (167). The resistor (166) and capacitor (167) are configured to slow the rise and fall time of the inverter input, thereby slowing the rise and fall time of the second driver circuit output.

As shown in FIG. 6, one or more additional driver circuits, such as the driver circuit shown to include PMOS (164) and NMOS (165) transistors, may also be included within the circuitry. Each driver stage may include a successively greater number of resistors (e.g., 170 and 168) and capacitors (e.g., 169 and 171). In this manner, each driver circuit has an increasingly higher time constant. Therefore, each of the driver circuits turns on at a successively later point in time. In this manner, the output impedance Z_{S} of the source (100; FIG. 1) decreases over time. However, with reference to the diagram of FIG. 1, the configuration of FIG. 6 results in a voltage Va at node N2 that is over-damped.

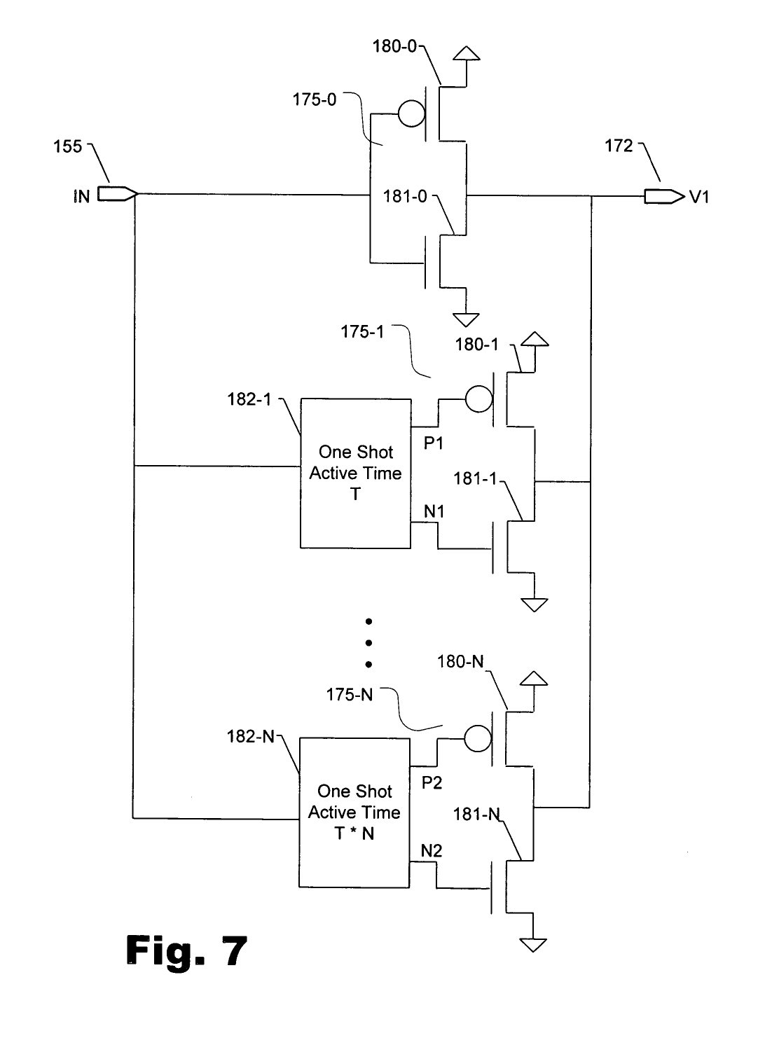

FIG. 7 is a diagram illustrating exemplary circuitry configured to reduce ringing by incrementally increasing the output impedance Zₛ of the digital signal source (100). The output impedance Z_{S} may be incrementally increased until it reaches a predetermined value (e.g., the value of the impedance of the transmission line (102; FIG. 1)). As will be described in more detail below, the circuitry of FIG. 7 is configured to result in a voltage Va at node N2 in the exemplary configuration of FIG. 1 that is critically damped.

As shown in FIG. 7, the circuitry may include a number of parallel driver circuits (175). FIG. 7 shows that any number N of driver circuits (175) may be included within the circuitry. Each driver circuit (175) includes a PMOS transistor (180) and an NMOS transistor (181). For example, the first driver circuit (175-0) includes PMOS transistor (180-0) and NMOS transistor (181-0). The size of each of the PMOS and NMOS transistors (180, 181) may be chosen such that the output signal V1 (172) is maintained at a desired state when the source (100; FIG. 1) is in steady state or direct current (DC) operation.

In some examples, driver circuits 175-1 through 175-N are controlled by a number of one shot circuits (182). One shot circuits (182) are known in the art and may be designed as best serves a particular application. Each one shot circuit (182) is configured to produce a single pulse with a duration of T*N, where the value of T may be selected as best serves a particular application. For example, driver circuit (175-1) is controlled by one shot circuit (182-1) and is configured to produce a single pulse with a duration of T. Likewise, driver circuit (175-N) is controlled by one shot circuit (182-N) and is configured to produce a single pulse with a duration of T*N.

In some embodiments, each driver circuit (175) is configured to initially turn on at the same time. With each of the driver circuits (175) enabled, the output impedance Z_{S} of the source (100; FIG. 1) is relatively low. This enables the voltage Va at node N2 of the circuit of FIG. 1 to closely follow V1. However, as time progresses, driver circuits (175-1 through 175-N) are configured to progressively turn off, thereby progressively increasing the output impedance Z_{S} of the source (100; FIG. 1). The increased output impedance Z_{S} reduces the slew rate of the signal Va such that the voltage Va at node N2 of the circuit of FIG. 1 is critically damped. In this manner, signal ringing is reduced or eliminated.

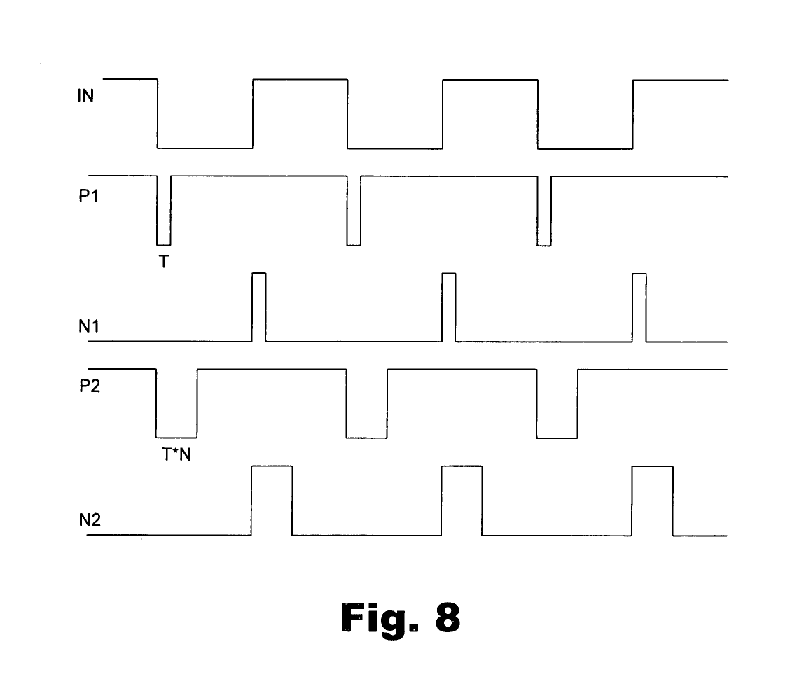

FIG. 8 shows a timing diagram that illustrates an exemplary method of operation of the circuitry of FIG. 7. The lines labeled IN, P1, P2, N1 and N2 represent the voltage on the nodes correspondingly labeled in FIG. 7. When IN goes from high to low, P1 and P2 go low, thereby turning on the PMOS transistors (180-1, 180-N) and pulling the output V1 high. At this point, each of the driver circuits (175) are on and the output impedance Z_{S} is relatively low.

After time T, as shown in FIG. 8, P1 goes back high, thereby turning driver circuit (175-1) off while all the other driver circuits (175-1) remain on. When driver circuit (175-1) turns off, the output impedance Z_{S} incrementally increases.

The process continues, with each successive driver circuit (175) after driver circuit (175-1) turning off. Finally, as shown in FIG. 8, P2 goes high after an elapsed time of T*N, thereby turning off the last driver circuit (175-N). At this point, the output impedance Z_{S} is at its maximum.

The process is repeated when the input signal IN goes from a low state to a high state. However, in this case, the NMOS transistors (181) are responsible for successively turning off the transistors. For example, when IN goes from high to low, N1 and N2 go high, thereby turning on the PMOS transistors (181-1, 181-N) and pulling the output V1 low. At this point, each of the driver circuits (175) are on and the output impedance Z_{S} is relatively low.

After time T, as shown in FIG. 8, N1 goes back low, thereby turning driver circuit (175-1) off while all the other driver circuits (175-1) remain on. When driver circuit (175-1) turns off, the output impedance Z_{S} incrementally increases.

The process continues, with each successive driver circuit (175) after driver circuit (175-1) turning off. Finally, as shown in FIG. 8, N2 goes low after an elapsed time of T*N, thereby turning off the last driver circuit (175-N). At this point, the output impedance Z_{S} is at its maximum.

In some examples, the circuitry of FIG. 7 is configured to allow for very fast signals because the rise and fall times thereof are not significantly reduced. The circuitry may be programmed to increase the output impedance Z_{S} in steps to ensure critically damped behavior and thereby reduce signal ringing over a wide variety of load conditions.

Additionally or alternatively, the circuitry of FIG. 7 may be configured to minimize or eliminate crobar or shoot through current. Shoot through current is current that flows from a positive power supply directly to a negative supply for the short time that the input to the transistors included within the source (100; FIG. 1) is at a middle voltage. In some embodiments, the present systems and methods may be used to completely eliminate shoot through current in drivers 175-1 through 175-N.

In some embodiments, the circuitry of FIG. 7 may be programmed to maintain the output impedance Z_{S} of the digital signal source (100; FIG. 1) such that it is constant over time. In this manner, the digital signal output driver circuit may additionally or alternatively be used to drive resistive loads in addition to or in place of capacitive loads.

The preceding description has been presented only to illustrate and describe embodiments of the invention. It is not intended to be exhaustive or to limit the invention to any precise form disclosed. Many modifications and variations are possible in light of the above teaching.

What is claimed is:

1. A system for reducing ringing of a signal generated by a digital signal source circuit, said system comprising:
a number of driver circuits configured to incrementally increase an output impedance of said source circuit;
wherein said increase in said output impedance is configured to reduce said ringing of said signal.

2. The system of claim 1, further comprising:
a transmission line coupled to said source circuit, said transmission line having a characteristic impedance;
wherein said driver circuits are further configured to incrementally increase said output impedance to a value that matches said characteristic impedance.

3. The system of claim 2, wherein said transmission line comprises at least one of a cable, wire, chip bond wire, circuit board wiring, and circuit board trace.

4. The system of claim 1, further comprising:
a number of one shot circuits configured to control an operation of one or more of said driver circuits.

5. The system of claim 1, wherein one of said driver circuits is configured to turn off every N times T seconds, wherein N is an integer greater than or equal to one and T is a period of time.

6. The system of claim 1, further comprising a receiving circuit configured to receive said signal.

7. The system of claim 6, wherein a voltage of said signal at an input of said receiving circuit is critically damped compared to a voltage of said signal at an output of said source circuit.

8. The system of claim 1, wherein said driver circuits are configured to operate in a parallel configuration.

9. The system of claim 1, wherein one or more of said driver circuits comprises a PMOS and an NMOS transistor.

10. The system of claim 1, wherein said source circuit comprises at least one of an integrated circuit, programmable logic device, microprocessor, digital signal processor, memory circuit, application specific integrated circuit, and field programmable gate array.

11. A method of reducing ringing of a signal generated by a digital signal source circuit, said method comprising:
incrementally increasing an output impedance of said source circuit;
wherein said increase in said output impedance is configured to reduce said ringing of said signal.

12. The method of claim 11, further comprising:
providing a number of driver circuits;
wherein said driver circuits are configured to incrementally increase said output impedance of said source circuit.

13. The method of claim 12, further comprising controlling an operation of one or more of said driver circuits with a number of one shot circuits.

14. The method of claim 12, further comprising turning off one of said driver circuits every N times T seconds, wherein N is an integer greater than or equal to one and T is a period of time.

15. The method of claim 11, further comprising incrementally increasing said output impedance to a value that matches a characteristic impedance of a transmission line connected to said source circuit.

16. The method of claim 11, further comprising:
providing a receiving circuit configured to receive said signal; and
incrementally increasing said output impedance of said source circuit such that a voltage of said signal at an input of a receiving circuit is critically damped compared to a voltage of said signal at an output of said source circuit.

17. A system for reducing ringing of a signal on a transmission line, said system comprising:
means for generating said signal; and
means for incrementally increasing an output impedance of said means for generating said signal;
wherein said increase in said output impedance is configured to reduce said ringing of said signal.

18. The system of claim 17, further comprising means for controlling said means for incrementally increasing said output impedance of said means for generating said signal.

19. The system of claim 17, further comprising means for incrementally increasing said output impedance to a value that matches a characteristic impedance of said transmission line.

20. The system of claim 17, further comprising means for receiving said signal.
